(19) United States
(12) Patent Application Publication
(10) Pub. No.: US 2014/0104012 A1
(43) Pub. Date: Apr. 17, 2014

(54) OSCILLATOR COMPENSATION CIRCUITS

(71) Applicant: Accusilicon USA Inc., Santa Clara, CA (US)

(72) Inventors: Yi Zhou, San Ramon, CA (US); Hongzhi Zheng, Hayward, CA (US)

(73) Assignee: Accusilicon USA Inc., Santa Clara, CA (US)

(21) Appl. No.: 14/051,352

(22) Filed: Oct. 10, 2013

Related U.S. Application Data
(60) Provisional application No. 61/713,446, filed on Oct. 12, 2012.

(51) Int. Cl. H03L 7/00

(52) U.S. Cl. CPC H03L 7/00
USPC 331/176

(57) ABSTRACT

A system and method is provided for controlling frequency of an oscillator. The system includes two or more temperature sensing circuits configured to generate temperature sensing signals corresponding to temperatures obtained by the two or more temperature sensing circuits. The system also includes a reference signal generation circuit configured to generate a reference signal and a first curve function generation circuit coupled to the two or more temperature sensing circuits and the reference signal generation circuit. The first curve function generation circuit is configured to provide two or more curve-generating signals based on the temperature sensing signals and the reference signal. The system further includes a summing circuit coupled to the first curve function generation circuit. The summing circuit is configured to provide, based on the two or more curve-generating signals, a first signal for controlling the frequency of the oscillator.

### CROSS REFERENCE TO RELATED APPLICATION

This application claims the benefit of priority to U.S. provisional Application No. 61/713,446, filed with the United States Patent and Trademark Office on Oct. 12, 2012, and entitled “OSCILLATOR COMPENSATION CIRCUITS”, which is hereby incorporated by reference in its entirety.

### TECHNICAL FIELD

The subject matter of the present application relates to methods and circuits for controlling frequency of an oscillator circuit, in particular, to methods and circuits for reducing frequency variation of crystal oscillators by compensating environmental condition variations such as temperature changes.

### BACKGROUND INFORMATION

Oscillators are widely used in digital as well as analog integrated circuits for generating critical clocking signals. Oscillators may include crystal oscillators, voltage-controlled oscillators, voltage-controlled crystal oscillators and many other types of oscillators. While a crystal oscillator can often provide a relatively constant and accurate output frequency under fixed environmental conditions, the output frequency of a crystal oscillator may nevertheless still vary when environmental conditions vary. Because oscillators are widely used to generate critical clocking signals in many circuit applications, variations of the output frequency due to environmental condition variations are therefore not desired.

### SUMMARY

The present disclosure provides a system for controlling frequency of an oscillator. According to some embodiments, the system includes two or more temperature sensing circuits configured to generate temperature sensing signals corresponding to temperatures obtained by the two or more temperature sensing circuits. The system also includes a reference signal generation circuit configured to generate a reference signal and a first curve function generation circuit coupled to the two or more temperature sensing circuits and the reference signal generation circuit. The first curve function generation circuit is configured to provide two or more curve-generating signals based on the temperature sensing signals and the reference signal. The system further includes a summing circuit coupled to the first curve function generation circuit. The summing circuit is configured to provide, based on the two or more curve-generating signals, a first signal for controlling the frequency of the oscillator.

The present disclosure also provides a method for controlling frequency of an oscillator. According to some embodiments, the method includes generating two or more temperature sensing signals; generating a reference signal; providing two or more curve-generating signals based on the temperature sensing signals and the reference signal; and generating, based on the two or more curve-generating signals, a first signal for controlling the frequency of the oscillator.

The present disclosure further provides a system for controlling frequency of a voltage controlled oscillator. The system includes three or more temperature sensing circuits configured to generate temperature sensing voltages corresponding to temperatures obtained by the three or more temperature sensing circuits. The system also includes a reference signal generation circuit configured to generate a reference voltage and a first curve function generation circuit electrically coupled to the three or more temperature sensing circuits and the reference signal generation circuit. The first curve function generation circuit is configured to provide three or more curve-generating signals based on the temperature sensing voltages and the reference voltage. The three or more curve-generating signals have different signal levels and different curves. The first curve function generation circuit is also configured to provide a first signal for controlling the frequency of the oscillator. The first signal corresponds to the sum of the three or more curve-generating signals. The system further includes a second curve function generation circuit configured to provide a second signal. The second signal has a linear relation with respect to temperature variations. The system further includes an adder configured to generate, based on the first signal and the second signal, a control voltage for controlling the frequency of the oscillator.

### BRIEF DESCRIPTION OF THE DRAWINGS

FIG. 1 is a diagram illustrating exemplary relation of two varying signals and a sum of the two varying signals, with respect to temperature variations.

FIG. 2A is a block diagram illustrating an exemplary oscillator control circuit.

FIG. 2B is a diagram illustrating exemplary relation between an output signal of the exemplary oscillator control circuit shown in FIG. 2A and temperature variations.

FIG. 3A is a schematic diagram of an exemplary embodiment of the oscillator control circuit shown in FIG. 2A.

FIG. 3B is a schematic diagram of an exemplary summing circuit.

FIG. 4A is a block diagram illustrating another exemplary oscillator control circuit.

FIG. 4B is a diagram illustrating exemplary relation between an output signal of the exemplary oscillator control circuit shown in FIG. 4A and temperature variations.

FIG. 5A is a schematic diagram of an exemplary embodiment of the oscillator control circuit shown in FIG. 4A.

FIG. 5B is a schematic diagram of another exemplary summing circuit.

FIG. 5C is a diagram illustrating exemplary current-temperature relation corresponding to the currents shown in FIG. 5A.

FIG. 6A is a schematic diagram of another exemplary embodiment of the oscillator control circuit shown in FIG. 4A.

FIG. 6B is a schematic diagram of another exemplary summing circuit.

FIG. 6C is a diagram illustrating exemplary current-temperature relation corresponding to the currents shown in FIG. 6A.

FIG. 7A a block diagram illustrating an exemplary temperature-compensated voltage-controlled crystal oscillator (TC-VCXO) circuit.

FIG. 7B is a diagram illustrating exemplary relation between a control signal of the exemplary TC-VCXO circuit shown in FIG. 7A and temperature variations.

FIG. 8A is a schematic diagram of an exemplary temperature sensing circuit.

FIG. 8B is a diagram illustrating exemplary relation between a temperature sensing voltage shown in FIG. 8A and temperature variations.

FIG. 9 is a flowchart representing an exemplary method for controlling frequency of an oscillator.

### DETAILED DESCRIPTION OF THE EMBODIMENTS

Reference will now be made in detail to the exemplary embodiments consistent with the embodiments disclosed herein, the examples of which are illustrated in the accompanying drawings. Wherever possible, the same reference numbers will be used throughout the drawings to refer to the same or similar parts.

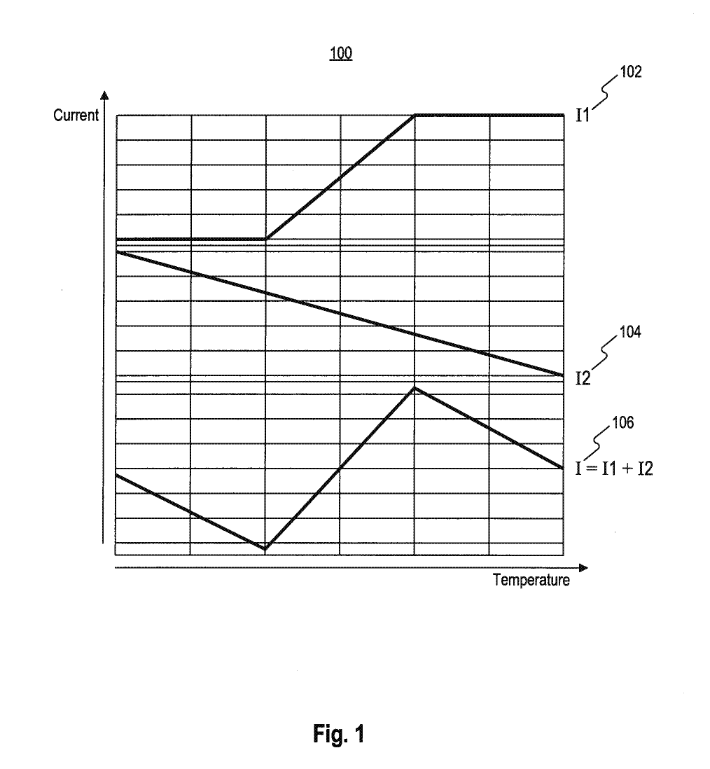

FIG. 1 is a diagram 100 illustrating exemplary relation of two varying signals and a sum of the two varying signals, with respect to the temperature variation. The signals and the sum of the signals can be voltage signals or current signals. Using current signals as an example, diagram 100 illustrates a first current I1 102, a second current I2 104, and a sum of first current I1 102 and second current I2 104, i.e., a sum current I 106. First current I1 102 and second current I2 104 can represent, for example, curve-generating current signals generated in response to temperature sensing signals. Temperature sensing signals, such as temperature sensing voltages, can be generated in response to variations of temperatures obtained by temperature sensing circuits. The temperature sensing signals and circuits are described in details below.

As shown in FIG. 1, first current I1 102 is illustrated as a current curve varying from a low value to a high value. Second current I2 104 is illustrated as a current curve varying from a higher value to a lower value. The variations of the first current I1 102 and second current I2 104 can be in response to, for example, temperature variations. That is, the horizontal axis of diagram 100 can represent the temperature variations and the vertical axis of diagram 100 can represent the current variations corresponding to the temperature variations. Moreover, first current I1 102 and second current I2 104 can be summed, added, or superimposed to generate sum current I 106.

In some embodiments, as shown in FIG. 1, first current I1 102 can have a non-linear current curve and second current I2 104 can have a linear current curve. A linear curve has a first order component and may not have higher order components. As a result, a linear current curve can have a constant slope and thus represent a first order relation (e.g., a straight-line type relation) between the current variations and the temperature variations. On the other hand, a non-linear curve can have a first order component and higher order (e.g., second and third order) components. As a result, a non-linear current curve can have more than one slope with respect to temperature variations and thus can represent a higher order relation (e.g., a segmented or curved type relation) between the current variations and the temperature variations. Moreover, after first current I1 102 and second current I2 104 are added, summed, or superimposed, sum current I 106 can also have a non-linear curve, which can have higher order (e.g., third order) components. First current I1 102 and second current I2 104 can be generated from, for example, a non-linear curve function generation circuit and a linear curve function generation circuit, respectively.

As an example, a non-linear curve function generation circuit can include two or more differential circuits. A differential circuit can have two input signals, i.e., a first input signal and a second input signal. The first input signal can be a reference voltage signal that has a substantially constant voltage. The second input signal can be a varying voltage signal generated from, for example, a temperature sensing circuit in response to the temperature variations. Because the temperature variations sensed by different temperature sensing circuit may be different, various voltage signals can be generated. Therefore, depending on the differences of the voltage levels between the two input signals, the currents flowing through different differential circuits (e.g., current I1 102, and current I2 104) can have various current levels and various current curves. The currents having various current levels and various current curves (e.g., current I1 102, and current I2 104) can then be added, summed, or superimposed to generate a non-linear current having higher order (e.g., third order) components (e.g., current I 106). Exemplary non-linear curve function generation circuit and linear curve function generation circuit are described in detail below.

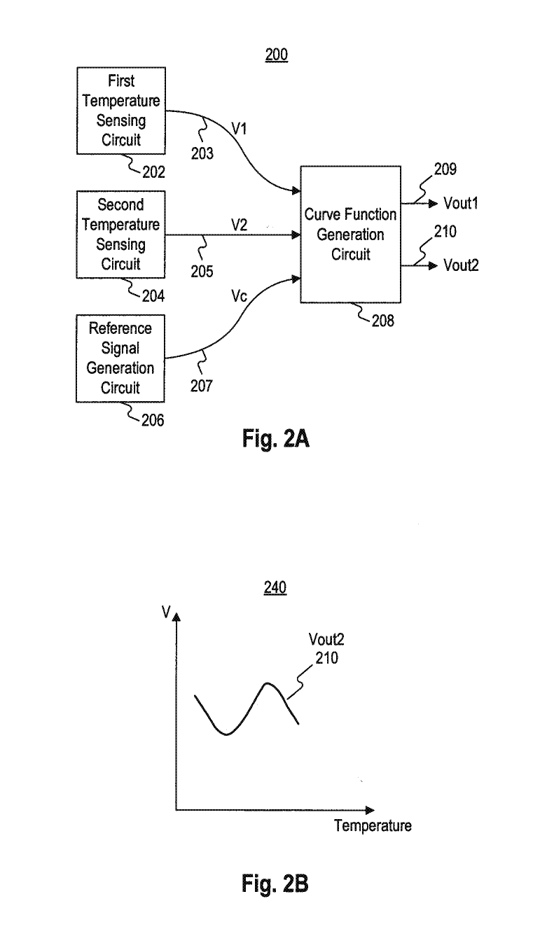

FIG. 2A is a block diagram illustrating an exemplary oscillator control circuit 200. Oscillator control circuit 200 can include a first temperature sensing circuit 202, a second temperature sensing circuit 204, a reference signal generation circuit 206, and a curve function generation circuit 208. Oscillator control circuit 200 can also include other circuits, such as a voltage or current summing circuit (not shown in FIG. 2A), which can sum, add, or superimpose two or more voltages of currents. It is appreciated that oscillator control circuit 200 can also include any other desired circuit elements.

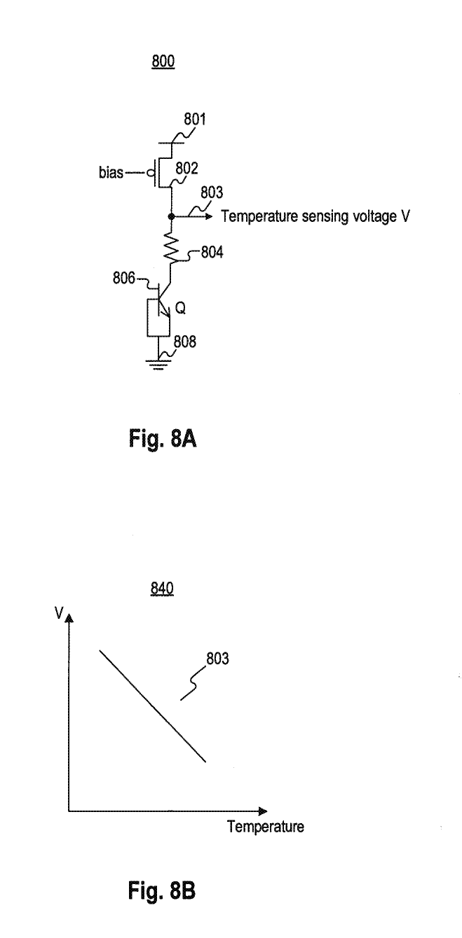

In some embodiments, first temperature sensing circuit 202 and second temperature sensing circuit 204 can obtain temperature by, for example, sensing or detecting the environmental temperature variations as their input signals. Based on the obtained temperature variations, first temperature sensing circuit 202 and second temperature sensing circuit 204 can generate a temperature sensing signal such as temperature sensing voltages V1 203 and V2 205. Temperature sensing voltages V1 203 and V2 205 can vary in response to the variations of the temperature obtained by first temperature sensing circuit 202 and second temperature sensing circuit 204, respectively. As a result, temperature sensing voltages V1 203 and V2 205 can represent or substantially represent the variations of the temperature. An exemplary temperature sensing circuit is described in detail below corresponding to FIGS. 8A-8B. In some embodiments, for collecting temperature conditions at different locations on an integrated-circuit chip or a device, one or more temperature sensing circuits, such as first temperature sensing circuit 202 and second temperature sensing circuit 204, can be placed at each location. In some embodiments, one or more temperature sensing circuits can be placed at the same location.

As shown in FIG. 2A, in some embodiments, oscillator control circuit 200 can also include reference signal generation circuit 206, which can generate a reference signal (e.g., a reference voltage signal Vc 207) that is constant or substantially constant with respect to environmental condition variations, such as temperature variations. As an example, reference signal generation circuit 206 can include a bandgap voltage reference generation circuit capable of providing substantially constant reference voltages across a desired range of temperature variations. Moreover, the reference signal (e.g., reference voltage signal Vc 207) can have any value that is desired.

As shown in FIG. 2A, in some embodiments, oscillator control circuit 200 can also include curve function generation circuit 208. Curve function generation circuit 208 receives inputs signals (e.g., temperature sensing voltages V1 203 and V2 205, and reference voltage signal Vc 207) from temperature sensing circuits 202 and 204 and reference signal generation circuit 206. After receiving the input signals, curve function generation circuit 208 can compare, for example, the value of each of temperature sensing voltages V1 203 and V2 205 to the value of reference voltage signal Vc 207. As an example, curve function generation circuit 208 can compare both temperature sensing voltages V1 203 and V2 205 with reference voltage signal Vc 207 and generates output signals Vout1 209 and Vout2 210.

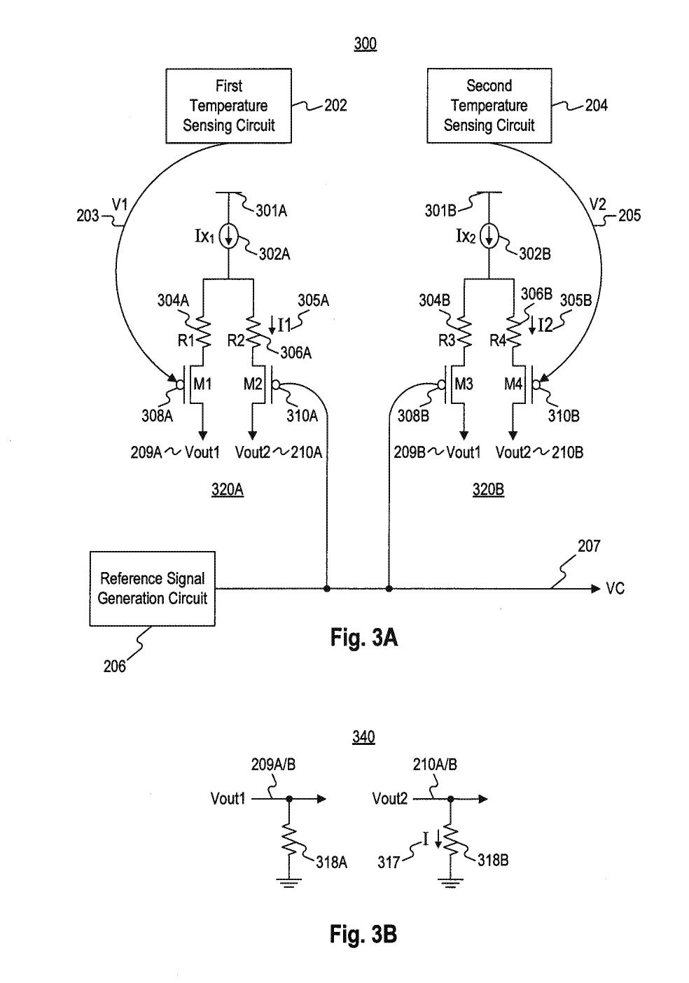

In some embodiments, curve function generation circuit 208 can also provide two or more curve-generating current signals (e.g., current I1 305A and I2 305B shown in FIG. 3A), which can be added, summed, or superimposed to generate a sum current described below. In some embodiments, curve function generation circuit 208 can generate output signals as voltage signals (e.g., output signals Vout1 209 and Vout2 210). In some embodiments, curve function generation circuit 208 can generate output signals as current signals instead of voltage signals. Curve function generation circuit 208 can also convert the output voltage signals to output current signals and vice versa. Curve function generation circuit 208 is further described in detail below.

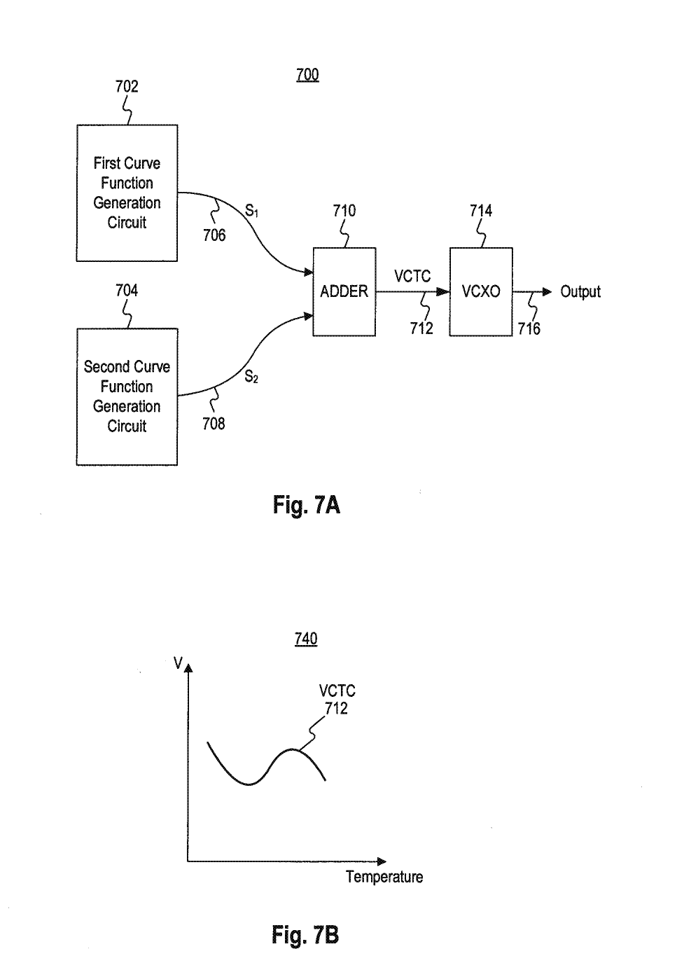

FIG. 2B is a diagram 240 illustrating exemplary relation between an output signal (e.g., output signal Vout2 210) of the exemplary oscillator control circuit 200 shown in FIG. 2A and temperature variations. In some embodiments, output signal Vout2 210 is derived from, or corresponds to, the temperature variations obtained by first temperature sensing circuit 202 and second temperature sensing circuit 204. As a result, output signal Vout2 210 can be used for controlling, such as compensating, the frequency variation of an oscillator (e.g., a voltage controlled oscillator, i.e., VCXO) caused by the temperature variations. As shown in FIG. 2B, the curve of output signal Vout2 210 can have higher order, such as a second and/or third order, components. The higher order components can have an impact on the shape of the curve of output signal Vout2 210. By adjusting the curve of output signal Vout2 210, fine tuning of a control voltage for an oscillator (e.g., a VCXO) and a better matching to the oscillator's frequency curve can be provided. Details of using the oscillator control circuit 200 for controlling oscillators are described below corresponding to FIGS. 7A-7B.

FIG. 3A is a schematic diagram of an exemplary embodiment 300 of oscillator control circuit 200 as shown in FIG. 2A. It is readily appreciated by one of ordinary skill in the art that the illustrated blocks and circuit elements in FIG. 3A can be altered in their numbers or their relative configurations. Exemplary embodiment 300 can also include additional blocks or circuit elements.

As shown in FIG. 3A, exemplary embodiment 300 can include first and second temperature sensing circuits 202 and 204; reference signal generation circuit 206; and differential circuits 320A and 320B. Differential circuits 320A and 320B can be included in curve function generation circuit 208 shown in FIG. 2A. In FIG. 3A, first and second temperature sensing circuits 202 and 204 and reference signal generation circuit 206 can be similar or substantially similar to those described corresponding to FIG. 2A and thus will not be described here.

As shown in FIG. 3A, in some embodiments, differential circuit 320A can include a power supply 301A, a current source 302A, one or more (e.g., two) resistors R1 304A and R2 306A, and one or more (e.g., two) transistor devices M1 308A and M2 310A. Similarly, differential circuit 320B can include a power supply 301B, a current source 302B, resistors R3 304B and R4 306B, and transistor devices M3 308B and M4 310B.

It is readily appreciated by one of ordinary skill in the art that the number of circuit elements, such as resistors and transistors, can be any number not limited to that shown in FIG. 3A. Transistor devices (e.g., M1 308A, M2 310A, M3 308B, and M4 310B) can be either p-type devices or n-type devices, such as p-type Metal-Oxide-Semiconductor (PMOS) or n-type Metal-Oxide-Semiconductor (NMOS) devices. The transistor devices can also have same or different sizes including transistor width and length.

As shown in FIG. 3A, in differential circuit 320A, power supply 301A can be electrically coupled to current source 302A. Power supply 301A can provide electrical power to differential circuit 320A. The voltage of power supply 301A may vary depending on the applications. Current source 302A can provide a constant or substantially constant current. In some embodiments, current source 302A can include a large-size transistor device controlled by a feedback circuit (not shown) so that the output current of the current source can be maintained substantially constant.

As shown in FIG. 3A, differential circuit 320A can include a left branch comprising resistor R1 304A and transistor device M1 308A, and a right branch comprising the resistor R2 306A and transistor device M2 310A. One terminal of resistor R1 304A and one terminal of the resistor R2 306A are electrically coupled to current source 302A. And the other terminals of resistor R1 304A and resistor R2 306A are electrically coupled to terminals, such as source terminals, of transistor devices M1 308A and M2 310A (shown as p-type transistor devices in FIG. 3A), respectively. Because current source 302A is electrically coupled to both the left and the right branches of the differential circuit 320A, a current I×1 provided by current source 302A is divided between the left and right branches. That is, the sum of the current flowing through the left branch and that of the right branch equals or substantially equals current I×1 provided by current source 302A.

As shown in FIG. 3A, transistor device M1 308A includes a gate terminal electrically coupled to first temperature sensing circuit 202. As a result, the gate terminal of transistor device M1 308A is controlled by temperature sensing voltage V1 203 generated from first temperature sensing circuit 202. The gate terminal of transistor device M2 310A is electrically coupled to reference signal generation circuit 206. Therefore, the gate terminal of transistor device M2 310A receives reference voltage signal Vc 207 generated by reference signal generation circuit 206. As described above, reference voltage signal Vc 207 can be constant or substantially constant.

In some embodiments, if temperature sensing voltage V1 203 and reference voltage signal Vc 207 are different, transistor devices M1 308A and M2 310A are under different operating conditions because they receive different control voltages at their gate terminals. As a result, the current flowing through transistor device M1 308A, i.e., the left branch, and the current flowing through transistor device M2 310A, i.e., the right branch, can be different. As an example, if temperature sensing voltage V1 203 has a value that is less than that of reference voltage signal Vc 207, the current flowing through transistor device M1 308A can be greater than the current flowing through transistor device M2 310A. Therefore, if transistor devices M1 308A and M2 310A are PMOS devices, transistor device M1 308A can have a greater gate-to-source voltage than that of transistor device M2 310A. On the other hand, if transistor devices M1 308A and M2 310A are NMOS devices, transistor device M1 308A can have a smaller gate-to-source voltage than that of transistor device M2 310A. Accordingly, because the currents flowing through the left and the right branches of differential circuit 320A can be different, the voltage levels of output signal Vout1 209A associated with the left branch and output signal Vout2 210A associated with the right branch can also be different.

As described above, differential circuit 320B can include power supply 301B, current source 302B, resistors R3 304B and R4 306B, and transistor devices M3 308B and M4 310B. Differential circuit 320B can have a similar or substantially similar configuration as that of differential circuit 320A. For example, differential circuit 320B receives temperature sensing voltage V2 205 from second temperature sensing circuit 204 through transistor device M4 310B in its right branch; and receives reference voltage signal Vc 207 generated by reference signal generation circuit 206 through transistor device M3 308B in its left branch. The operation of differential circuit 320B can be the same or similar to that of differential circuit 320A, and thus is not described here. Differential circuit 320B can generated output signal Vout1 209B and output signal Vout2 210B. Because the currents flowing through the left and the right branches of differential circuit 320B can be different, the voltage levels of output signal Vout1 209B associated with the left branch and output signal Vout2 210B associated with the right branch can also be different.

FIG. 3B is a schematic diagram of an exemplary summing circuit 340. As described above, output signals Vout1 209A/B and Vout2 210A/B (shown in FIG. 3A) can be voltage signals. In some applications, output signals Vout1 209A/B and Vout2 210A/B may need to be converted from voltage signals to current signals. Therefore, in some embodiments, one or more instances of summing circuit 340 can be coupled to or integrated with differential circuits 320A and 320B. As an example, resistors 318A and 318B in summing circuit 340 can be electrically coupled to differential circuit 320A, and similarly differential circuit 320B. Specifically, resistor 318A and 318B can be coupled to output signal Vout1 209A and output signal Vout2 210A, respectively, for converting output signal Vout1 209A and output signal Vout2 210A from voltage signals to current signals. In some embodiments, in summing circuit 340, one terminal of resistor 318A and one terminal of resistor 318B can be electrically coupled to electrical ground. The other terminals of resistor 318A and resistor 318B can be electrically coupled to output signal Vout1 209A and output signal Vout2 210A, respectively. Similarly, one or more instances of summing circuit 340 can also be electrically coupled to differential circuit 320B. As a result, by using one or more instances of summing circuit 340, output voltage signals Vout1 209A/B and Vout2 210A/B can be converted to current signals. It is appreciated that summing circuit 340 can also be any other summing circuit that is desired.

Referring to both FIGS. 3A and 3B, in some embodiments, summing circuit 340 can also add, sum, or superimpose current signals. As an example, one or more instances of summing circuit 340, through terminals of resistor 318B, can be coupled to output signal Vout2 210A and output signal Vout2 210B. As a result, the current flowing through both right branches of differential circuits 320A and 320B (i.e., current I1 305A and current I2 305B) can be summed, added, or superimposed to generate a sum current (e.g., sum current I 317 flowing through resistor 318B). As described above, current I1 305A and current I2 305B can have different values and curves. As an example, in some embodiments, the sizes of the transistor devices and the resistors in differential circuits 320A and 320B can be different such that same temperature sensing voltages V1 203 and V2 205 may generate different currents I1 305A and I2 305B. As another example, in some embodiments, differential circuits 320A and 320B receive different temperature sensing voltages V1 203 and V2 205 and therefore generates different currents I1 305A and I2 305B.

Currents I1 305A and I2 305B can also be linear or non-linear. Currents I1 305A and I2 305B can be each at a different level so that a coarse and/or a fine tuning of sum current I 317 can be realized. As an example, current I1 305A can be at a high level so that it represents the coarse tuning. That is, adjusting current I1 305A can cause a relatively large change of sum current I 317. On the other hand, current I2 305B can be at a low level so that it represents the fine tuning. That is, adjusting current I2 305B can cause a relatively small change of sum current I 317.

Moreover, because sum current I 317 is derived from, or corresponds to, the temperature variations obtained by first temperature sensing circuit 202 and second temperature sensing circuit 204, sum current I 317 can be used for controlling or compensating the frequency change of the oscillator due to the temperature variations. As described above, the curve of sum current I 317 can have higher order, such as a third order, components. The higher order components can have an impact on the shape of the curve of sum current I 317. Therefore, by adjusting the shape of the curve of sum current I 317, a better matching to the oscillator's frequency curve can be provided.

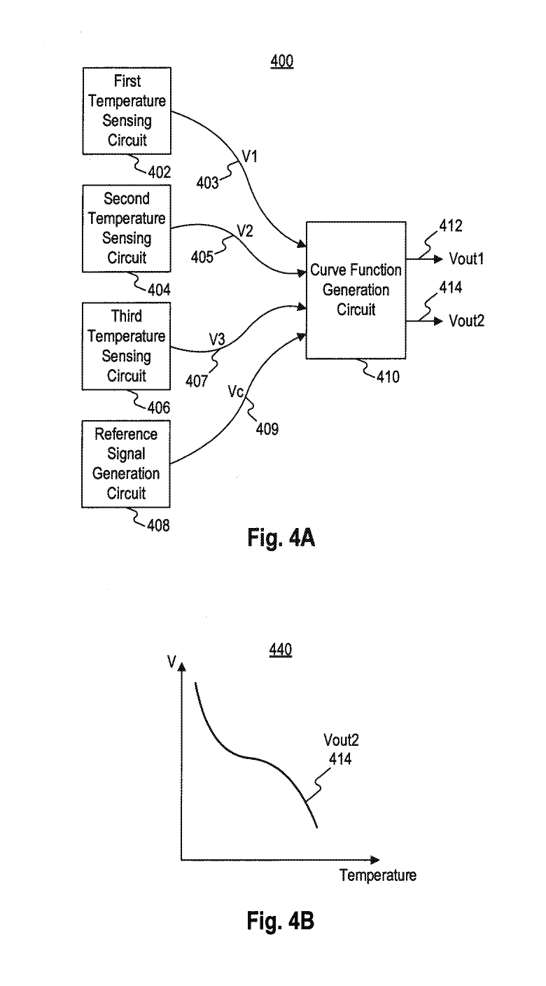

FIG. 4A is a block diagram illustrating another exemplary oscillator control circuit 400. Oscillator control circuit 400 can include a first temperature sensing circuit 402, a second temperature sensing circuit 404, a third temperature sensing circuit 406, a reference signal generation circuit 408, and a curve function generation circuit 410. Oscillator control circuit 400 can also include other circuits, such as a summing circuit (not shown in FIG. 4A), which can generate the sum of the voltages of currents. It is appreciated that oscillator control circuit 400 can also include any other desired circuit elements.

First temperature sensing circuit 402, second temperature sensing circuit 404, third temperature sensing circuit 406, and reference signal generation circuit 408 can be the same as or similar to the temperature sensing circuits and reference signal generation circuit shown in FIG. 2A and thus will not be described here. Based on the corresponding temperature variations, first temperature sensing circuit 402, second temperature sensing circuit 404, and third temperature sensing circuit 406 can generate output signals such as temperature sensing voltages V1 403, V2 405, and V3 407. Temperature sensing voltages V1 403, V2 405, and V3 407 can vary in response to the variations of the temperature obtained by first temperature sensing circuit 402, second temperature sensing circuit 404, and third temperature sensing circuit 406, respectively. As a result, temperature sensing voltages V1 403, V2 405, and V3 407 can represent or substantially represent the variations of the temperature obtained. An exemplary temperature sensing circuit is described in detail below corresponding to FIGS. 8A-8B.

Curve function generation circuit 410 can receive input signals (e.g., temperature sensing voltages V1 403, V2 405, and V3 407, and reference voltage signal Vc 409) from first temperature sensing circuit 402, second temperature sensing circuit 404, third temperature sensing circuit 406, and reference signal generation circuit 408. After receiving the input signals, curve function generation circuit 410 can compare, for example, the value of each of temperature sensing voltages V1 403, V2 405, and V3 407 to the value of reference voltage signal Vc 409. As an example, curve function generation circuit 410 compares all temperature sensing voltages V1 403, V2 405, and V3 407 with reference voltage signal Vc 409 and generates output signal Vout1 412 and Vout2 414.

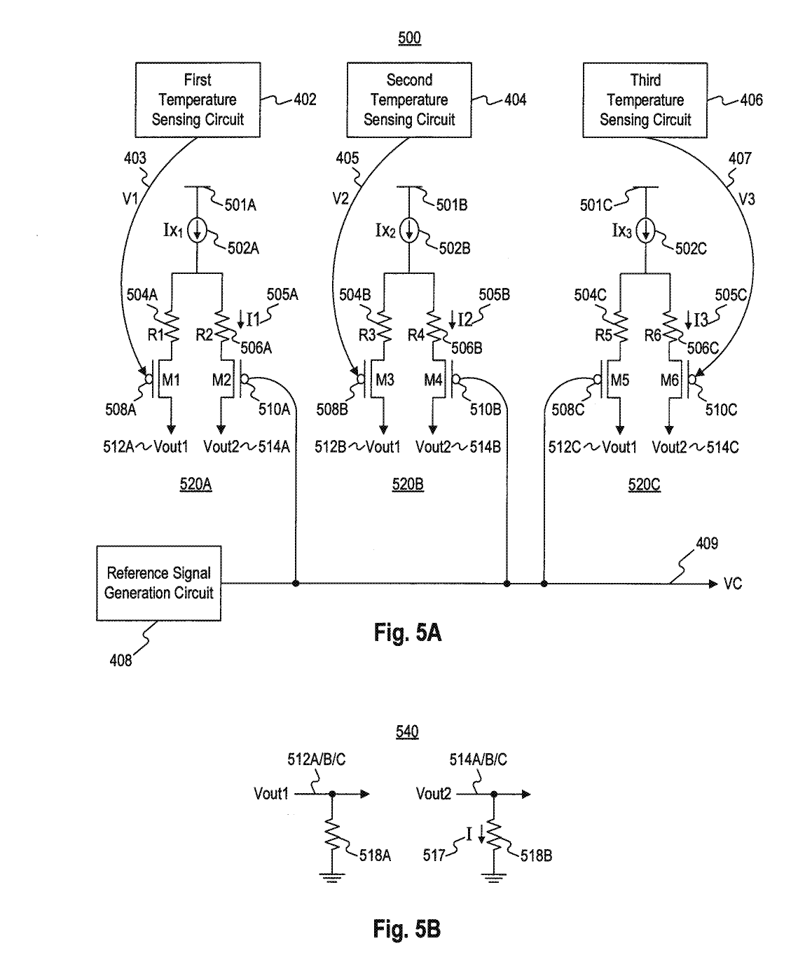

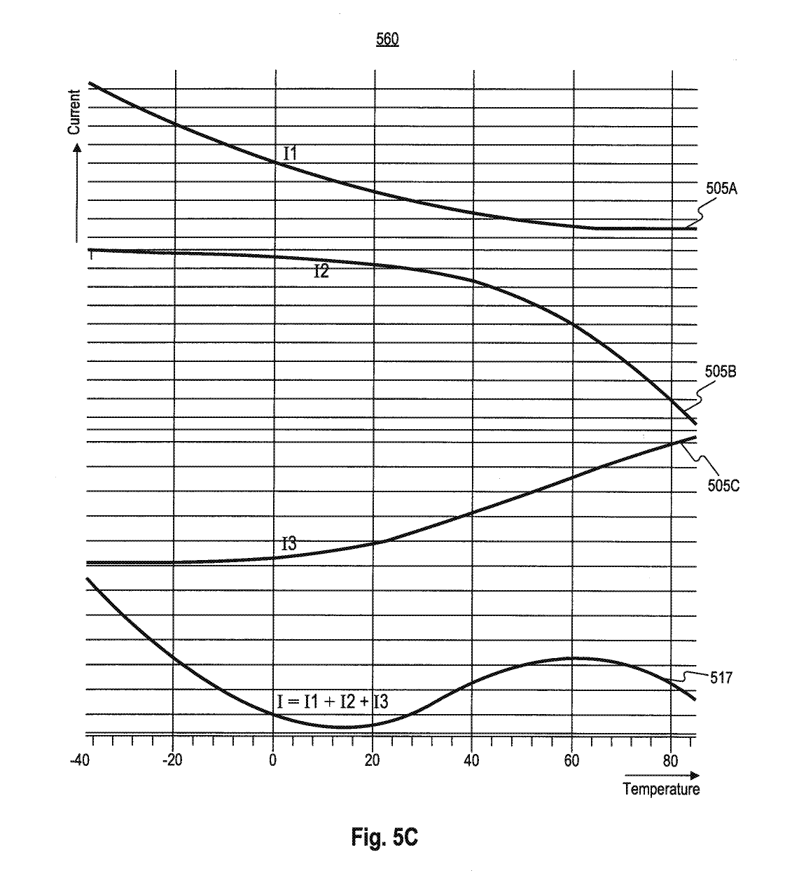

In some embodiments, curve function generation circuit 410 can also generate one or more (e.g., three) current signals (current signals I1 505A, I2 505B, and I3 505C) shown in FIG. 5A), which are added, summed, or superimposed together to generate a sum current described below. In some embodiments, curve function generation circuit 410 generates output signals as voltage signals (e.g., output signals Vout1 412 and Vout2 414). In some embodiments, curve function generation circuit 410 can generate output signals as current signals instead of voltage signals. Curve function generation circuit 410 can also convert the output voltage signals to output current signals and vice versa. Curve function generation circuit 410 is further described in detail below.

FIG. 4B is a diagram 440 illustrating exemplary relation between an output signal (e.g., output signal Vout2 414) of the exemplary oscillator control circuit 400 shown in FIG. 4A and temperature variations. In some embodiments, output signal Vout2 414 is derived from, or corresponds to, the temperature variations obtained by first temperature sensing circuit 402, second temperature sensing circuit 404, and third temperature sensing circuit 406. As a result, output signal Vout2 414 can be used for controlling, such as compensating, the frequency variation of an oscillator (e.g., a VCXO) caused by the temperature variations. As shown in FIG. 4B, the curve of output signal Vout2 414 can have higher order, such as a second and/or third order, components. The higher order components can have an impact on the shape of the curve of output signal Vout2 414. By adjusting the curve of output signal Vout2 414, fine tuning of a control voltage for an oscillator (e.g., a VCXO) and a better matching to the oscillator's frequency curve can be provided.

FIG. 5A is a schematic diagram of an exemplary embodiment 500 of oscillator control circuit 400 as shown in FIG. 4A. It is readily appreciated by one of ordinary skill in the art that the illustrated blocks and circuit elements in FIG. 5A can be altered in their numbers or their relative configurations. Exemplary embodiment 500 can also include additional blocks or circuit elements.

As shown in FIG. 5A, exemplary embodiment 500 can include first, second, and third temperature sensing circuits 402, 404, and 406, reference signal generation circuit 408, and differential circuits 520A, 520B, and 520C. Differential circuits 520A, 520B, and 520C can be included in curve function generation circuit 410 shown in FIG. 4A. In FIG. 5A, first, second, and third temperature sensing circuits 402, 404, and 406 and reference signal generation circuit 408 can be similar or substantially similar to those described corresponding to FIG. 2A and thus will not be described here.

As shown in FIG. 5A, in some embodiments, differential circuits 520A/B/C can include power supplies 501A/B/C, current sources 502A/B/C, one or more resistors R1 504A, R2 506A, R3 504B, R4 506B, R5 504C, and R6 506C, and one or more transistor devices M1 508A, M2 510A, M3 508B, M4 510B, M5 508C, and M6 510C. It is readily appreciated by one of ordinary skill in the art that the number of circuit elements, such as resistors and transistor devices, can be any number not limited to that shown in FIG. 5A. The transistor devices (e.g., M1 508A and M2 510A) can be either p-type devices or n-type devices, such as PMOS or NMOS devices. The transistor devices can also have same or different sizes including transistor width and length.

Moreover, in FIG. 5A, the circuit configurations of differential circuits 520A/B/C, including configurations of power supplies 501A/B/C, current sources 502A/B/C, resistors R1 504A, R2 506A, R3 504B, R4 506B, R5 504C, and R6 506C, and transistor devices M1 508A, M2 510A, M3 508B, M4 510B, M5 508C, and M6 510C, can be substantially the same as or similar to those of differential circuits 320A/B described above, and thus will not be described. However, the parameters of the circuit elements in FIG. 5A, such as the sizes of the transistor devices, may or may not be the same as those corresponding elements shown in FIG. 3A.

As shown in FIG. 5A, in some embodiments, transistor devices M1 508A and M3 508B can include gate terminals that are electrically coupled to first temperature sensing circuit 402 and second temperature sensing circuit 404, respectively. As a result, the gate terminals of transistor device M1 508A and M3 508B are controlled by temperature sensing voltages V1 403 and V2 405 generated from first temperature sensing circuit 402 and second temperature sensing circuit 404, respectively. The gate terminals of transistor devices M2 510A and M4 510B are electrically coupled to reference signal generation circuit 408. Therefore, the gate terminals of transistor device M2 510A and M4 510B receive reference voltage signal Vc 409 generated by the reference signal generation circuit 408. As described above, reference voltage signal Vc 409 can be constant or substantially constant.

In some embodiments, differential circuit 520C receives temperature sensing voltage V3 407 from temperature sensing circuit 406 through the gate terminal of transistor device M6 510C in the right branch of differential circuit 520C. Differential circuit 520C also receives reference voltage signal Vc 409 provided by the reference signal generation circuit 408 through the gate terminal of transistor device M5 508C in the left branch of differential circuit 520C. It is appreciated by one of ordinary skill in the art that the circuit configuration of differential circuits 520A/B/C can also be any other type such that it enables comparison of temperature sensing voltages V1 403, V2 405, and V3 407, and reference voltage signal Vc 409.

In some embodiments, if temperature sensing voltage V1 403 and reference voltage signal Vc 409 are different, transistor devices M1 508A and M2 510A are under different operating conditions because they receive different control voltages at their gate terminals. As a result, the current flowing through transistor device M1 508A and the current flowing through transistor device M2 510A can be different. As an example, if temperature sensing voltage V1 403 has a value that is less than that of reference voltage signal Vc 409, the current flowing through transistor device M1 508A can be greater than the current flowing through transistor device M2 510A. Therefore, if transistor devices M1 508A and M2 510A are PMOS devices, transistor device M1 508A can have a greater gate-to-source voltage than that of transistor device M2 510A. On the other hand, if transistor devices M1 508A and M2 510A are NMOS devices, transistor device M1 508A can have a smaller gate-to-source voltage than that of transistor device M2 510A. Accordingly, because the currents flowing through the left and the right branches of differential circuit 520A can be different, the voltage levels of output signal Vout1 512A associated with the left branch and output signal Vout2 514A associated with the right branch can also be different.

As shown in FIG. 5A, differential circuit 520B can have a similar or substantially similar configuration as that of differential circuit 520A. For example, differential circuit 520B receives temperature sensing voltage V2 405 from second temperature sensing circuit 404 through transistor device M3 508B in its left branch; and receives reference voltage signal Vc 409 generated by reference signal generation circuit 408 through transistor device M4 510B in its right branch. The operation of differential circuit 520B can be the same or similar to that of differential circuit 520A, and thus is not described here. Differential circuit 520B can generate output signal Vout1 512B and output signal Vout2 514B. Because the currents flowing through the left and the right branches of differential circuit 520B can also be different, the voltage levels of output signal Vout1 512B associated with the left branch and output signal Vout2 514B associated with the right branch can also be different.

Differential circuit 520C can have a similar or substantially similar configuration as that of differential circuit 520A/B. For example, differential circuit 520C receives temperature sensing voltage V3 407 from third temperature sensing circuit 406 through transistor device M6 510C in its right branch; and receives reference voltage signal Vc 409 generated by reference signal generation circuit 408 through transistor device M5 508C in its right branch. The operation of differential circuit 520C can be the same or similar to that of differential circuit 520A/B, and thus is not described here. Differential circuit 520C can generated output signal Vout1 512C and output signal Vout2 514C. Because the currents flowing through the left and the right branches of differential circuit 520C can be different, the voltage levels of output signal Vout1 512C associated with the left branch and output signal Vout2 514C associated with the right branch can also be different.

FIG. 5B is a schematic diagram of another exemplary summing circuit 540. As described above, output signals Vout1 512A/B/C and Vout2 514A/B/C (shown in FIG. 5A) can be voltage signals. In some applications, output signals Vout1 512A/B/C and Vout2 514A/B/C may need to be converted from voltage signals to current signals. Therefore, in some embodiments, one or more instances of summing circuit 540 can be coupled to or integrated with differential circuits 520A/B/C. As an example, differential circuit 520A, and similarly differential circuits 520B and 520C, can to coupled to resistors 518A and 518B of summing circuit 540. Specifically, resistors 518A and 518B can be coupled to output signal Vout1 512A and output signal Vout2 514A, respectively, for converting voltage signals to current signals. In some embodiments, in summing circuit 540, one terminal of resistor 518A and one terminal of resistor 518B can be electrically coupled to electrical ground. The other terminals of resistor 518A and resistor 518B can be electrically coupled to output signal Vout1 512A and output signal Vout2 514A, respectively. Similarly, one or more instances of summing circuit 540 can also be coupled to differential circuits 520B and 520C. As a result, by using one or more instances of summing circuit 540, output voltage signals Vout1 512A/B/C and Vout2 514A/B/C can be converted to current signals. It is appreciated that summing circuit 540 can also be any other summing circuit that is desired.

Referring to both FIGS. 5A and 5B, in some embodiments, summing circuit 540 can also add, sum, or superimpose current signals. As an example, one or more instances of summing circuit 540, through terminals of resistor 518B, can be coupled to output signals Vout2 514A, Vout2 514B, and Vout2 514C. As a result, the current flowing through right branches of differential circuits 520A, 520B, and 520C (e.g., current I1 505A associated with output signal Vout2 514A, current I2 505B associated with output signal Vout2 514B, and current I3 505C associated with output signal Vout2 514C) can be summed, added, or superimposed to generate a sum current (e.g., sum current I 517 flowing through resistor 518B). Currents I1 505A, I2 505B, and I3 505C can be the same or different. As an example, in some embodiments, the sizes of the transistor devices and the resistors in differential circuits 520A, 520B, and 520C can be different such that same input voltages may generate different currents I1 505A, I2 505B, and I3 505C. As another example, in some embodiments, differential circuits 520A, 520B, and 520C receive different temperature sensing voltages V1 403, V2 407, and V3 407 and therefore generates different currents I1 505A, I2 505B, and I3 505C.

FIG. 5C is a diagram 560 illustrating exemplary current-temperature relation corresponding to currents I1 505A, I2 505B, and I3 505C. As shown in FIG. 5C, currents I1 505A, I2 505B, and I3 505C can be linear or non-linear. Currents I1 505A, I2 505B, and I3 505C can be at different levels so that coarse and/or fine tuning of sum current I 517 can be provided. As an example, current I1 505A may be at a highest level so that it represents the coarsest tuning. That is, adjusting current I1 505A can cause a relatively large change of sum current I 517. On the other hand, current I3 505C can be at a lowest level so that it represents the finest tuning. That is, adjusting current I3 505C can cause a smallest change of sum current I 517. Current I2 505B can be at a middle level between currents I1 505A and I3 505C. Thus, adjusting current I2 505B can cause a medium change of sum current I 517.

Moreover, because sum current I 517 is derived from, or corresponds to, the temperature variations sensed by first, second, and third temperature sensing circuits 402, 404, and 406, sum current I 517 can be used for controlling or compensating the frequency change of the oscillator due to the temperature variations. In some embodiments, first, second, and third temperature sensing circuits 402, 404, and 406 can generate different currents I1 505A, I2 505B, and I3 505C in response to same or different temperature variations. Furthermore, the curves of currents I1 505A, I2 505B, and I3 505C can have higher order, such as third order, components. As a result, sum current I 517 can also have higher order, such as a third order, components. The higher order components can have an impact on the shape of the curve of sum current I 517. Additionally, because currents I1 505A, I2 505B, and I3 505C correspond to three temperature sensing circuits shown in FIG. 5A, an additional degree of freedom for adjusting sum current I 517 can be provided as compared to the degree of freedom for adjusting sum current I 317 as shown in FIG. 3A, where two temperature sensing circuits are used. With an additional degree of freedom for adjusting the current level and the current curve of sum current I 517, an improved fine tuning of a control voltage for an oscillator (e.g., a VCXO) and a better matching to the oscillator's frequency curve can be provided.

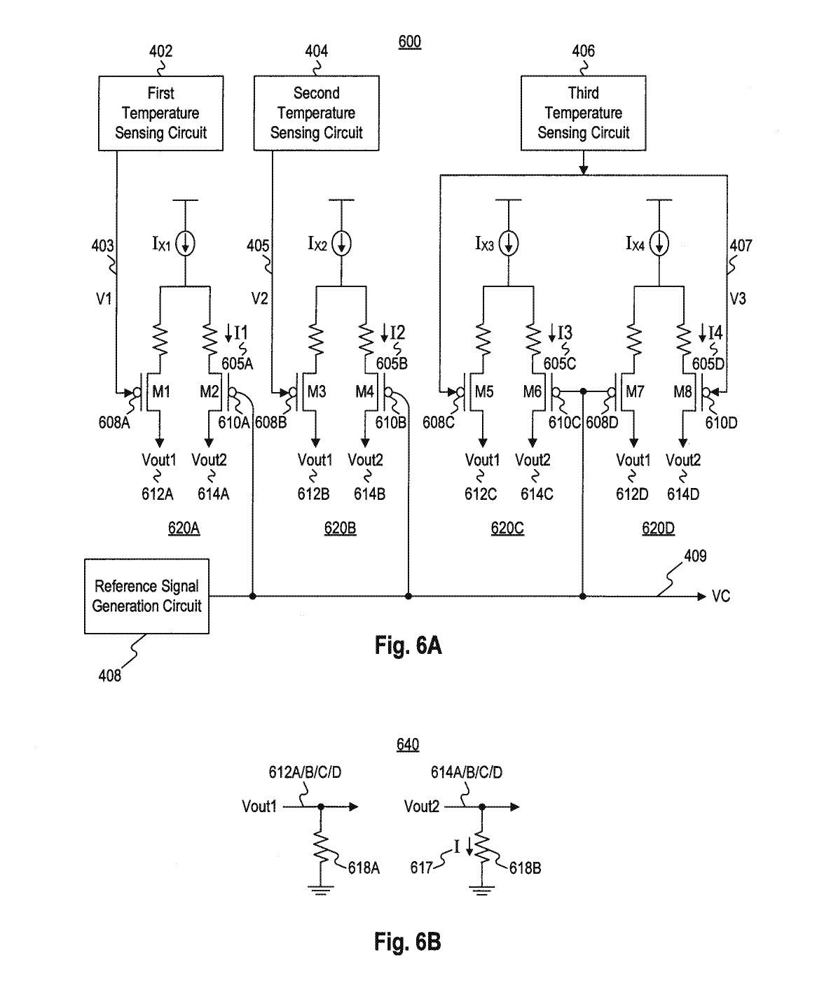

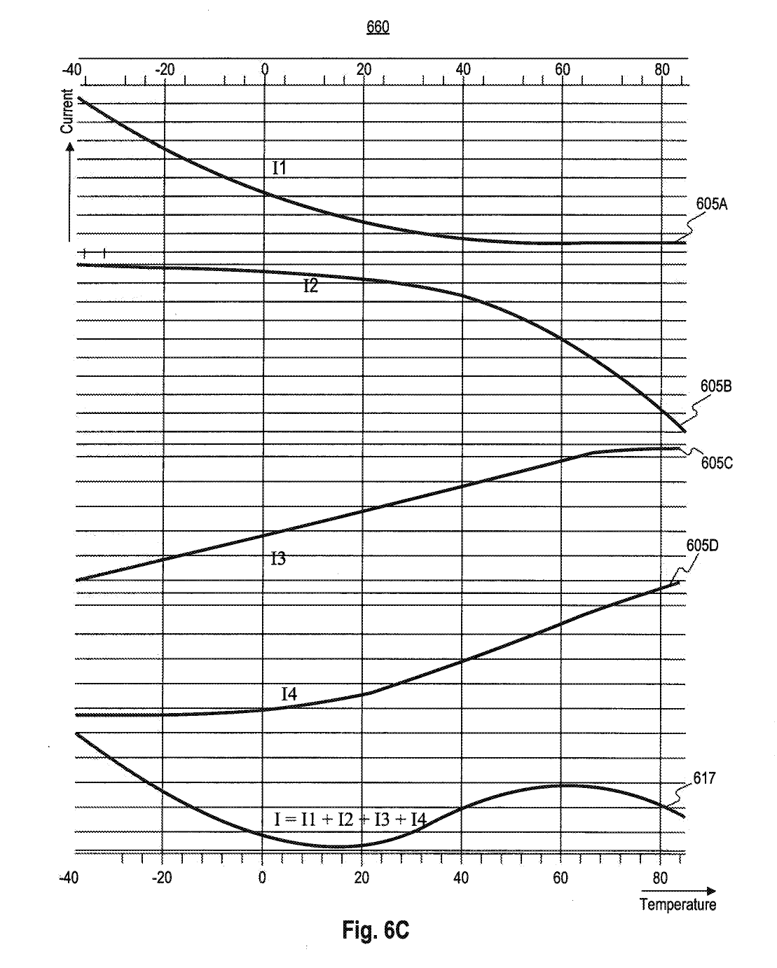

FIG. 6A is a schematic diagram of another exemplary embodiment 600 of oscillator control circuit 400 as shown in FIG. 4A. It is readily appreciated by one of ordinary skill in the art that the illustrated blocks and circuit elements in FIG. 6A can be altered in their numbers or their relative configurations. Exemplary embodiment 600 can also include additional blocks or circuit elements.

As shown in FIG. 6A, exemplary embodiment 600 can include first, second, and third temperature sensing circuits 402, 404, and 406; reference signal generation circuit 408; and one or more (e.g., four) differential circuits 620A, 620B, 620C, and 620D. Differential circuits 620A, 620B, 620C, and 620D can be included in curve function generation circuit 410 shown in FIG. 4A. In FIG. 6A, first, second, and third temperature sensing circuits 402, 404, and 406 and reference signal generation circuit 408 can be similar or substantially similar to those described corresponding to FIG. 2A and thus will not be described here.

As shown in FIG. 6A, in some embodiments, differential circuits 620A/B/C/D can include similar circuit elements as those shown in differential circuits 520A/B/C in FIG. 5A. For example, differential circuits 620A/B/C/D can include, among other things, one or more transistor devices M1 608A, M2 610A, M3 608B, M4 610B, M5 608C, M6 610C, M7 608D, and M8 610D. It is readily appreciated by one of ordinary skill in the art that the number of circuit elements, such as resistors and transistors, can be any number not limited to that shown in FIG. 6A. The transistor devices (e.g., M1 608A and M2 610A) can be either p-type devices or n-type devices, such as PMOS or NMOS devices. The transistor devices can also have same or different sizes including transistor width and length. In FIG. 6A, the circuit configurations of differential circuits 620A/B/C/D can be substantially the same as or similar to those of differential circuits 520A/B/C described above, and thus will not be described here. However, the parameters of the circuit elements in FIG. 6A, such as the sizes of the transistor devices, may or may not be the same as those corresponding elements shown in FIG. 5A.

As shown in FIG. 6A, in some embodiments, transistor devices M1 608A and M3 608B can include gate terminals that are electrically coupled to first temperature sensing circuit 402 and second temperature sensing circuit 404, respectively. As a result, the gate terminals of transistor device M1 608A and M3 608B are controlled by the temperature sensing voltages V1 403 and V2 405 generated from first temperature sensing circuit 402 and second temperature sensing circuit 404, respectively. The gate terminals of transistor devices M2 610A and M4 610B are electrically coupled to reference signal generation circuit 408. Therefore, the gate terminals of transistor device M2 610A and M4 610B receive reference voltage signal Vc 409 generated by the reference signal generation circuit 408. As described above, reference voltage signal Vc 409 can be constant or substantially constant.

In some embodiments, differential circuits 620C and 620D receive temperature sensing voltage V3 407 from temperature sensing circuit 406 through the gate terminal of transistor device M5 608C in the left branch of differential circuit 620C and the gate terminal of transistor device M8 610D in the right branch of differential circuit 620D. Differential circuits 620C and 620D also receive reference voltage signal Vc 409 generated by reference signal generation circuit 408 through the gate terminal of transistor device M6 610C in the right branch of differential circuit 620C and the gate terminal of transistor device M7 608D in the left branch of differential circuit 620D. It is appreciated by one of ordinary skill in the art that the circuit configuration of differential circuits 620A/B/C/D can also be any other type such that it enables comparison of temperature sensing voltages V1 403, V2 405, and V3 407, and reference voltage signal Vc 409.

Differential circuits 620A and 620B can operate, such as compare temperature sensing voltages V1 403 and V2 405 with reference voltage signal Vc 409, in a substantially the same or similar manner as that described above corresponding to differential circuits 520A and 520B. Differential circuits 620C and 620D can also operate, such as compare temperature sensing voltage V3 407 with reference voltage signal Vc 409 in a substantially the same or similar manner as that described above corresponding to differential circuits 520A and 520B. Thus, operation of differential circuits 620A/B/C/D is not described here. Similar to those described above, differential circuits 620A/B/C/D can generated output signal Vout1 612A/B/C/D and output signal Vout2 614A/B/C/D. Because the currents flowing through the left and the right branches of any of differential circuits 620A/B/C/D can be different, the voltage levels of output signal Vout1 612A/B/C/D can be different from the corresponding output signal Vout2 614 A/B/C/D.

FIG. 6B is a schematic diagram of another exemplary summing circuit 640. As described above, output signals Vout1 612A/B/C/D and Vout2 614A/B/C/D (shown in FIG. 6A) can be voltage signals. In some applications, output signals Vout1 612A/B/C/D and Vout2 614A/B/C/D may need to be converted from voltage signals to current signals. Therefore, in some embodiments, one or more instances of summing circuit 640 can be coupled to or integrated with differential circuits 620A/B/C/D. As an example, differential circuit 620A, and similarly differential circuit 620B, 620C, and 620D, can be coupled to resistors 618A and 618B. Specifically, resistors 618A and 618B can be coupled to output signal Vout1 612A and output signal Vout2 614A, respectively, for converting voltage signals to current signals. In some embodiments, in summing circuit 640, one terminal of resistor 618A and one terminal of resistor 618B can be electrically coupled to electrical ground. The other terminals of resistor 618A and resistor 618B can be electrically coupled to output signal Vout1 612A and output signal Vout2 614A, respectively. Similarly, one or more instances of summing circuit 640 can also be coupled to differential circuits 620B, 620C, and 620D. As a result, by using one or more instances of summing circuit 640, output voltage signals Vout1 612A/B/C/D and Vout2 614A/B/C/D can be converted to current signals. It is appreciated that summing circuit 640 can also be any other summing circuit that is desired.

Referring to both FIGS. 6A and 6B, in some embodiments, summing circuit 640 can also add, sum, or superimpose current signals. As an example, one or more instances of summing circuit 640, through terminals of one or more instances of resistor 618B, can be coupled to output signals Vout2 614A, Vout2 614B, Vout2 614C, and Vout2 614D. As a result, the current flowing through right branches of differential circuits 620A, 620B, 620C, and 620D (e.g., current I1 605A associated with output signal Vout2 614A, current I2 605B associated with output signal Vout2 614B, current I3 605C associated with output signal Vout2 6140, and current I4 605D associated with output signal Vout2 614D) can be summed, added, or superimposed to generate a sum current (e.g., sum current I 617 flowing through resistor 618B). Moreover, currents I1 605A, I2 605B, I3 605C, and I4 605D can be the same or different. As an example, in some embodiments, the sizes of the transistor devices and the resistors in differential circuits 620A, 620B, 620C, and 620D can be different such that same input voltages may generate different currents I1 605A, I2 605B, I3 605C, and I4 605D. As another example, in some embodiments, differential circuits 620A, 620B, 620C, and 620D can receive different temperature sensing voltages V1 403, V2 405, and V3 407, and may generate different currents I1 605A, I2 605B, I3 605C, and I4 605D.

FIG. 6C is a diagram 660 illustrating exemplary current-temperature relation corresponding to currents I1 605A, I2 605B, I3 605C, and I4 605D. As shown in FIG. 6C, currents I1 605A, I2 605B, I3 605C, and I4 605D can be linear or non-linear. Currents I1 605A, I2 605B, I3 605C, and I4 605D can be at different levels so that coarse and/or fine tuning of sum current I 617 can be provided. As an example, current I1 605A may be at a highest level so that it represents the coarsest tuning. That is, adjusting current I1 605A can cause a largest change of sum current I 617. On the other hand, current I4 605D can be at a lowest level so that it represents the finest tuning. That is, adjusting current I4 605D can cause a smallest change of sum current I 617. Currents I2 605B and I3 605C can be at middle levels between currents I1 605A and I4 605C. Thus adjusting current I2 605B and I3 605C can cause medium levels of change of sum current I 617.

Moreover, because sum current I 617 is derived from, or corresponds to, the temperature variations sensed by first, second, and third temperature sensing circuits 402, 404, and 406, sum current I 617 can be used for controlling or compensating the frequency change of the oscillator due to the temperature variations. In some embodiments, first, second, and third temperature sensing circuits 402, 404, and 406 can generate different currents I1 605A, I2 605B, I3 605C, and I4 605D corresponding to same or different temperature variations. Furthermore, the curves of currents I1 605A, I2 605B, I3 605C, and I4 605D can have higher order, such as third order, components. As a result, sum current I 617 can also have higher order, such as a third order, components. The higher order components can have an impact on the shape of the curve of sum current I 617. Additionally, because currents I1 605A, I2 605B, I3 605C, and I4 605D correspond to four temperature sensing circuits shown in FIG. 6A, one additional degree of freedom for adjusting the level and the curve of sum current I 617 is provided as compared to the degree of freedom provided by embodiment 500 of oscillator control circuit 400 shown in FIG. 5A, where three temperature sensing circuits are used. With an additional degree of freedom to adjust the current level and the current curve of sum current I 617, a further improved fine tuning of a control voltage for an oscillator (e.g., a VCXO) and a better matching to the oscillator's frequency curve can be provided.

FIG. 7A is a block diagram illustrating an exemplary temperature-compensated voltage-controlled crystal oscillator (TC-VCXO) circuit 700. In FIG. 7A, it is readily appreciated by one of ordinary skill in the art that the illustrated blocks and circuit elements can be altered in their numbers or their relative configurations. TC-VXCO circuit 700 can also include additional blocks or circuit elements.

As shown in FIG. 7A, TC-VCXO circuit 700 can include a first curve function generation circuit 702, a second curve function generation circuit 704, an adder 710 and a voltage-controlled crystal oscillator (VCXO) 714. In FIG. 7A, first curve function generation circuit 702 can be any of the curve function generation circuits (e.g., curve function generation circuits 208 and 410) and their various embodiments described above in FIGS. 2A, 3A, 4A, 5A, and 6A. Therefore, first curve generation circuit 702 can generate a voltage or current signal (e.g., signal S1), which represents the temperature variations obtained by the temperature sensing circuits (e.g., first, second, and third temperature sensing circuits 402, 404, and 406 in FIG. 6A). The curve of signal S1 can have higher order (such as third order) components. First curve function generation circuit 702 can also be any variations or modifications of the curve function generation circuits and their various embodiments described above in FIGS. 2A, 3A, 4A, 5A, and 6A.

In FIG. 7A, second curve function generation circuit 704 can be any type of circuit that can generate a linear voltage or current signal (e.g., signal S2) with respect to the temperature variations. Signal S2 can be a signal that is, for example, in linear relation with its input signal within a partial or a whole input signal range. As an example, similar to first curve function generation circuit 702, the input signal to second curve function generation circuit 704 can be a temperature sensing signal generated from a temperature sensing circuit. And the output signal of second curve function generation circuit 704 can be a voltage or current signal that varies with a constant slope in response to the input temperature sensing signal. In some embodiments, second curve function generation circuit 704 can be an inverting amplifier receiving input signals from one or more temperature sensing circuits.

In FIG. 7A, adder 710 can be any type of circuits, digital or analog, that performs addition, summation, or superimposition of the input signals of adder 710. For example, adder 710 can be a mixer, a summing operational amplifier, a translinear or a Gilbert-type circuit, etc. Adder 710 can add, sum, or superimpose one or more input signals that are voltage signals or current signals (e.g., signals S1 and S2) and generate a corresponding output voltage or current signal (e.g., VCTC 712). The curve of VCTC 712 can have, for example, a desired curve and voltage level such that VCTC 712 can be provided as a control voltage for controlling frequency of an oscillator (e.g., VCXO 714). By using VCTC 712 as a control voltage, a better matching to the oscillator's frequency curve can also be provided.

FIG. 7B is a diagram 740 illustrating exemplary relation between VCTC 712 shown in FIG. 7A and the temperature variations. As shown in FIG. 7B, VCTC 712 can have any curve that is desired to provide control and matching of the oscillator's frequency curve.

Referring back to FIG. 7A, VCXO 714 can be, for example, a crystal oscillator with voltage controlled capacitors. Supplied with a control voltage (e.g., VCTC 712), VCXO 714 can partially or substantially adjust, such as tune, the dependence on temperature of the resonant frequency of the crystal oscillator of VCXO 714. That is, VCTC 712 can be supplied to VXCO 714 in order to control or compensate the frequency change of the crystal oscillator of VCXO 714. For example, a frequency variation of the crystal oscillator caused by a temperature variation can be compensated by applying a proper control voltage VCTC 712, which is then multiplied by the crystal oscillator's gain such that the frequency of the crystal oscillator can be increased or decreased to a desired value.

FIG. 8A illustrates an exemplary temperature sensing circuit 800. In FIG. 8A, it is readily appreciated by one of ordinary skill in the art that the illustrated blocks and circuit elements can be altered in their numbers or their relative configurations. Temperature sensing circuit 800 can also include additional blocks or circuit elements. Temperature sensing circuit 800 can be included in, for example, temperature sensing circuits 202 and 204 in FIGS. 2A and 3A; and temperature sensing circuits 402, 404, and 406 in FIGS. 4A, 5A, and 6A.

As shown in FIG. 8A, temperature sensing circuit 800 can include a power supply 801, a first transistor device 802, a resistor 804, a second transistor device 806, and an electrical ground 808. Power supply 801 can provide electrical power to temperature sensing circuit 800. First transistor device 802 can be a PMOS device electrically coupled to power supply 801 through its source terminal. First transistor device 802 can also be an NMOS device electrically coupled to power supply 801 through its drain terminal. The gate terminal of first transistor device 802 can be controlled by a biasing voltage such that first transistor device 802 can provide a desired current flowing through resistor 804 and second transistor device 806.

As shown in FIG. 8A, depending on whether first transistor device 802 is a PMOS or NMOS device, the drain or source terminal of first transistor device 802 is electrically coupled to a terminal of resistor 804. Resistor 804 can generate a voltage drop from a first terminal electrically coupled to first transistor device 802 to a second terminal electrically coupled to second transistor device 806. Resistor 804 can also limit the current flowing through temperature sensing circuit 800. The second terminal of resistor 804 is electrically coupled to a first terminal (e.g., a collector terminal) of second transistor device 806.

Second transistor device 806, as shown in FIG. 8A, can be a PNP-type bipolar transistor. In some embodiments, the second and third (e.g., the base and emitter) terminals of second transistor device 806 can be electrically coupled together, such that second transistor device 806 can function as a forward-biased PN junction diode device, which can be used as a temperature sensor. Second transistor device 806 (e.g., a forward-biased PN junction diode device) can exhibit a linear relationship between the forward-bias voltage and the temperature. Second transistor device 806 can have a negative temperature coefficient. It is readily appreciated by one skilled in the art that the second transistor device 806 can also be an NPN-type bipolar transistor, a diode, or any other type of device that may exhibit a linear voltage-temperature relationship. By using second transistor device 806, temperature sensing circuit 800 can generate a temperature sensing voltage V 803 that has a linear relationship with temperature variations.

FIG. 8B is a diagram 840 illustrating exemplary relation between a temperature sensing signal, such as temperature sensing voltage V 803, shown in FIG. 8A and the temperature variations. In some embodiments, temperature sensing voltage V 803 can be measured at the third (e.g. drain) terminal of first transistor device 802. In FIG. 8B, diagram 840 illustrates that temperature sensing voltage V 803 can vary linearly or substantially linearly with the temperature variations. Accordingly, temperature sensing circuit 800 can be used to measure the temperature variations in a linear manner.

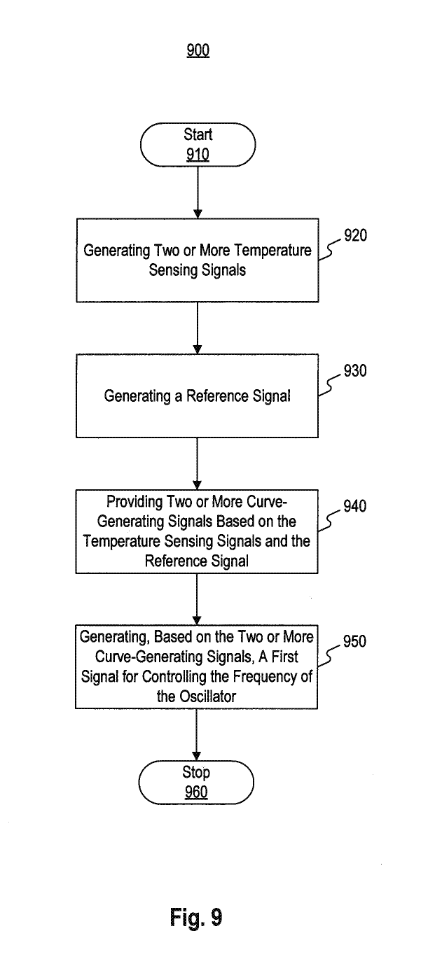

FIG. 9 is a flowchart representing an exemplary method for controlling frequency of an oscillator. It will be readily appreciated that the illustrated procedure can be altered to delete steps or further include additional steps. After initial step 910, a system (e.g., system 200), via two or more temperature sensing circuits (e.g., temperature sensing circuits 202 and 204), generates (920) two or more temperature sensing signals, such as temperature sensing voltages. Temperature sensing voltages can vary in response to the variations of the temperature obtained by the two or more temperature sensing circuits. As a result, temperature sensing voltages can represent or substantially represent the variation of the temperature. In some embodiments, temperature sensing signals can be generated by using a temperature sensor (e.g., a forward-biased PN junction diode device) that exhibits a linear relationship between the forward-bias voltage and the temperature.

As shown in FIG. 9, the system, via a reference signal generation circuit (e.g., reference signal generation circuit 206), generates (930) a reference signal that is constant or substantially constant with respect to environmental condition variations, such as temperature variations. As an example, the reference signal can be generated by a reference signal generation circuit (e.g., a bandgap voltage reference generation circuit) that is capable of providing substantially constant reference voltages across a desired range of temperature variations. Moreover, the reference signal can have any value that is desired.

After generating the temperature sensing signals and the reference signal, the system, via a curve function generation circuit (e.g., curve function generation circuit 208), provides (940) two or more curve-generating signals, such as currents, based on the temperature sensing signals and the reference signal. As described above, using differential circuits, the two or more curve-generating currents can be provided by comparing the reference signal and the corresponding temperature sensing signal. The two or more curve-generating currents can also have different current levels and different curves for providing coarse and fine tuning of the sum of the curve-generating currents and for providing better matching to the oscillator frequency curve.

After providing the two or more curve-generating signals, the system, via a summing circuit (e.g., summing circuit 340) generates (950), based on the two or more curve-generating signals, a first signal (e.g., sum current I 317) for controlling the frequency of the oscillator. The first signal can have a curve that includes one or more third or higher order components. And the curve of the first signal corresponds to the current levels and the curves of the two or more curve-generating currents.

After generating the first signal, method 900 can proceed to a stop 960. Method 900 can also proceed to further steps (not shown), including providing a second signal (e.g., signal S2 708), which can have a linear relation with respect to temperature variations; and generating, based on the first current and the second current, a control voltage for controlling the frequency of the oscillator. It is appreciated by one of ordinary skill in the art that method 900 can also be repeated as desired.

In the preceding specification, the subject matter has been described with reference to specific exemplary embodiments. It will, however, be evident that various modifications and changes may be made without departing from the broader spirit and scope of the subject matter as set forth in the claims that follow. The specification and drawings are accordingly to be regarded as illustrative rather than restrictive. Other embodiments may be apparent to those skilled in the art from consideration of the specification and practice of the embodiments disclosed herein.

What is claimed is:

1. A system for controlling frequency of an oscillator, the system comprising:
two or more temperature sensing circuits configured to generate temperature sensing signals corresponding to temperatures obtained by the two or more temperature sensing circuits;
a reference signal generation circuit configured to generate a reference signal;
a first curve function generation circuit coupled to the two or more temperature sensing circuits and the reference signal generation circuit, the first curve function generation circuit being configured to provide two or more curve-generating signals based on the temperature sensing signals and the reference signal and
a summing circuit coupled to the first curve function generation circuit, the summing circuit being configured to provide, based on the two or more curve-generating signals, a first signal for controlling the frequency of the oscillator.

2. The system of claim 1, wherein the first curve function generation circuit comprises two or more differential circuits, each of the two or more differential circuits including a pair of transistor devices configured to receive the reference signal and the corresponding temperature sensing signal.

3. The system of claim 2, wherein each of the two or more differential circuits is configured to compare the reference signal and the received corresponding temperature sensing signal.

4. The system of claim 2, wherein the transistor devices are p-type Metal-Oxide-Semiconductor (PMOS) devices or n-type Metal-Oxide-Semiconductor (NMOS) devices.

5. The system of claim 1, wherein the temperature sensing signals and the reference signal are voltage signals.

6. The system of claim 1, wherein the two or more curve-generating signals are current signals having different signal levels and different curves.

7. The system of claim 6, wherein the first signal has a curve that includes one or more third or higher order components, the curve of the first signal corresponding to the signal levels and the curves of the two or more curve-generating signals.

8. The system of claim 2, wherein the summing circuit includes one or more resistor devices coupled to the corresponding transistor devices.

9. The system of claim 1, wherein at least one of the temperature sensing circuits includes a bipolar device configured to obtain temperature variations and generating a temperature sensing voltage based on the obtained temperature variations.

10. The system of claim 1, wherein the reference signal generation circuit includes a bandgap voltage reference generation circuit configured to provide a substantially constant reference voltage with respect to temperature variations.

11. The system of claim 1, further comprising:
a second curve function generation circuit configured to provide a second signal, the second signal having a linear relation with respect to temperature variations; and
an adder configured to generate, based on the first signal and the second signal, a control signal for controlling the frequency of the oscillator.

12. The system of claim 11, wherein the oscillator is a voltage controlled oscillator.

13. A method for controlling frequency of an oscillator, the method comprising:
generating two or more temperature sensing signals;
generating a reference signal;
providing two or more curve-generating signals based on the temperature sensing signals and the reference signal; and
generating, based on the two or more curve-generating signals, a first signal for controlling the frequency of the oscillator.

14. The method of claim 13, wherein providing the two or more curve-generating signals based on the temperature sensing signals and the reference signal comprises comparing the reference signal and the corresponding temperature sensing signal.

15. The method of claim 13, wherein the temperature sensing signals and the reference signal are voltage signals.

16. The method of claim 13, wherein the two or more curve-generating signals are current signals having different signal levels and different curves.

17. The method of claim 16, wherein the first signal has a curve that includes one or more third or higher order components, the curve of the first signal corresponding to the signal levels and the curves of the two or more curve-generating signals.

18. The method of claim 13, wherein generating the temperature sensing signals comprises obtaining temperature variations and generating a temperature sensing voltage based on the obtained temperature variations.

19. The method of claim 13, wherein generating the reference signal comprises providing a substantially constant reference voltage with respect to temperature variations.

20. The method of claim 13, further comprising:
providing a second signal, the second signal having a linear relation with respect to temperature variations; and
generating, based on the first signal and the second signal, a control voltage for controlling the frequency of the oscillator.

21. The method of claim 20, wherein the oscillator is a voltage controlled oscillator.

22. A system for controlling frequency of a voltage controlled oscillator, the system comprising:
three or more temperature sensing circuits configured to generate temperature sensing voltages corresponding to temperatures obtained by the three or more temperature sensing circuits;
a reference signal generation circuit configured to generate a reference voltage;
a first curve function generation circuit electrically coupled to the three or more temperature sensing circuits and the reference signal generation circuit, the first curve function generation circuit being configured to:
provide three or more curve-generating signals based on the temperature sensing voltages and the reference voltage, wherein the three or more curve-generating signals have different signal levels and different curves, and
provide a first signal for controlling the frequency of the oscillator, wherein the first signal corresponds to the sum of the three or more curve-generating signals;
a second curve function generation circuit configured to provide a second signal, the second signal having a linear relation with respect to temperature variations; and
an adder configured to generate, based on the first signal and the second signal, a control voltage for controlling the frequency of the oscillator.
